(19) United States
(12) Patent Application Publication
(10) Pub. No.: US 2008/0128913 A1
(43) Pub. Date: Jun. 5, 2008

(54) TUNGSTEN INTERCONNECT SUPER STRUCTURE FOR SEMICONDUCTOR POWER DEVICES

(75) Inventors: Li-Shu Chen, Ellicott City, MD (US); Philip C. Smith, Ellicott City, MD (US); Steven M. Buchoff, Baltimore, MD (US); Joel Frederick Rosenbaum, Seabrook, MD (US); Joel Barry Schneider, Baltimore, MD (US); Witold J. Malkowski, Baltimore, MD (US)

Correspondence Address: SNELL & WILMER L.L.P. (Grumman), 600 ANTON BOULEVARD, SUITE 1400, COSTA MESA, CA, 92626, US

(73) Assignee: Northrop Grumman Systems Corporation, Los Angeles, CA (US)

(21) Appl. No.: 11/924,538

(22) Filed: Oct. 25, 2007

Related U.S. Application Data
(60) Provisional application No. 60/861,719, filed on Nov. 30, 2006.

(51) Int. Cl. H01L 23/48; H01L 21/4763

(52) U.S. Cl. 257/764; 438/648; 257/E21.575; 257/E23.163

(57) ABSTRACT

In one embodiment, the disclosure relates to a method for forming a semiconductor power device by depositing a first layer of TiW on a gate region and a source region, depositing a second layer of refractory metal over the first layer of TiW at the gate region, depositing a dielectric stack over the second layer of refractory metal and a portion of the first layer of TiW, depositing an etch stop layer over a portion of the dielectric stack, depositing an interconnect layer over the etch stop layer and the dielectric stack and depositing an etch mask over the interconnect layer.

### BACKGROUND

This application claims priority from U.S. Provisional Patent Application No. 60/861,719 filed on Nov. 30, 2006, entitled “TUNGSTEN INTERCONNECT SUPER STRUCTURE FOR SEMICONDUCTOR POWER DEVICES AND DEVICE FABRICATION METHOD FOR SELF-ALIGNED ION IMPLANTED HIGH POWER SiC STATIC INDUCTION TRANSISTOR” which is expressly incorporated herein in its entirety.

1. Field of the Disclosure

The present disclosure generally relates to a tungsten interconnect super structure for semiconductor power devices and more specifically to the formation of an interconnect for the sources, gates and gate bus within semiconductor power devices and more specifically the formation of an interconnect for the sources, gates and gate bus within semiconductor power devices using Tungsten.

2. Description of the Related Art

In semiconductor devices, gold is typically used as an electrical conductor within the device. A field effect transistor (FET), for example, includes sources, drains, gates and a bus for connecting the gates together. In many cases, gold is used as an interconnect for the sources, gates and gate bus. When radiofrequency (RF) power is input for a certain period of time, the resulting heat and thermal expansion can cause the source interconnect and occasionally the gate or gate bus interconnect, to fail catastrophically. For example, in a static induction transistor (SIT) using gold as the source interconnect, input RF power generates pulses from the source to the drain, thereby increasing the temperature of the device and causing thermal stresses which can induce catastrophic failure of the gold interconnect.

Thermal effects can delaminate the gold interconnect from the underlying structure. Furthermore, the gold at the top of the source interconnect can be thermally segregated (e.g., recrystalized), while the underlying refractive metals, such as TiW and W remain intact. Such metal interconnect failures present a serious reliability issue in the manufacturing of semiconductor power devices.

### SUMMARY

To improve the reliability of metal interconnects within semiconductor power devices, embodiments of the present disclosure use refractive metals, such as tungsten, molybdenum, titanium, etc. alone or in various combinations, as the interconnect metal. Additionally, various metal layers, such as Ti/Au/Ti, Ti/NiCr/Ti, Ti/Cr/Ti, etc., may be used as etch stops during the formation of the metal interconnect, such as during a reactive ion etching (RIE) process.

In one embodiment, the disclosure relates to a method for forming a semiconductor power device comprising: depositing a first layer of TiW (12) on a gate region (4a, 4b, 4c) and a source region (6a, 6b); depositing a second layer of refractory metal (14) over the first layer of TiW (12) at the gate region (4a, 4b, 4c); depositing a dielectric stack (16) over the second layer of refractory metal (14) and a portion of the first layer of TiW (12); depositing an etch stop layer (20, 22, 24) over a portion of the dielectric stack (16); depositing an interconnect layer (26, 28, 30) over the etch stop layer (20, 22, 24) and the dielectric stack (16); and depositing an etch mask (32, 34) over the interconnect layer (26, 28, 30).

In another embodiment, the disclosure relates to a method for forming a semiconductor power device comprising: depositing a first layer of TiW (12) on a gate region (4a, 4b, 4c) and a source region (6a, 6b); depositing a second layer of refractory metal (14) over the first layer of TiW at the gate region (4a, 4b, 4c); depositing a dielectric stack (16) over the second layer of refractory metal (14) and a portion of the first layer of TiW (12); depositing an etch stop layer (20, 22, 24) over a portion of the dielectric stack (16); depositing an interconnect layer (26, 28, 30) formed of TiW and W over the etch stop layer (20, 22, 24) and the dielectric stack (16); and depositing an etch mask (32, 34) formed of a layer of Ti, Pt, or a combination of Ti and Pt over the interconnect layer (26, 28, 30).

In still another embodiment, the disclosure relates to a semiconductor power device comprising: a gate region (4a, 4b, 4c) with a first layer of TiW (12) over the gate region; a source region (6a, 6b) with a first layer of TiW (12) over the source region; a second layer of refractory metal (14) over the first layer of TiW (12) at the gate region (4a, 4b, 4c); a dielectric stack (16) over the second layer of refractory metal (14) and a portion of the first layer of TiW (12); an etch stop layer (20, 22, 24) over a portion of the dielectric stack (16); an interconnect layer (26, 28, 30) formed of refractory metal over the etch stop layer (20, 22, 24) and the dielectric stack (16); and an etch mask (32, 34) over the interconnect layer (26, 28, 30).

### BRIEF DESCRIPTION OF THE DRAWINGS

These and other embodiments of the disclosure will be discussed in relation to the following exemplary and non-limiting drawings in which:

FIG. 1 depicts failure of a gold interconnect in conventional practices;

FIG. 2 depicts failure of a lower powered gold interconnect in conventional practices;

FIG. 3 depicts a side view of an ion implanted static induction transistor prior to the formation of a lower metal interconnect layer;

FIG. 4 depicts a side view of an ion implanted static induction transistor after formation of a lower metal interconnect layer;

FIG. 5 depicts a side view of an ion implanted static induction transistor after deposition of a dielectric stack;

FIG. 6 depicts a side view of an ion implanted static induction transistor after dielectric delineation and etch stop formation;

FIG. 7 depicts a side view of an ion implanted static induction transistor after an upper metal interconnect layer is formed;

FIG. 8 depicts an ion implanted static induction transistor after reactive ion etching is used to open windows through an upper metal interconnect layer to etch stop regions;

FIG. 9 is a flowchart of an exemplary method for forming a semiconductor power device according to an embodiment of the disclosure; and

FIG. 10 depicts an embodiment of the disclosure.

### DETAILED DESCRIPTION

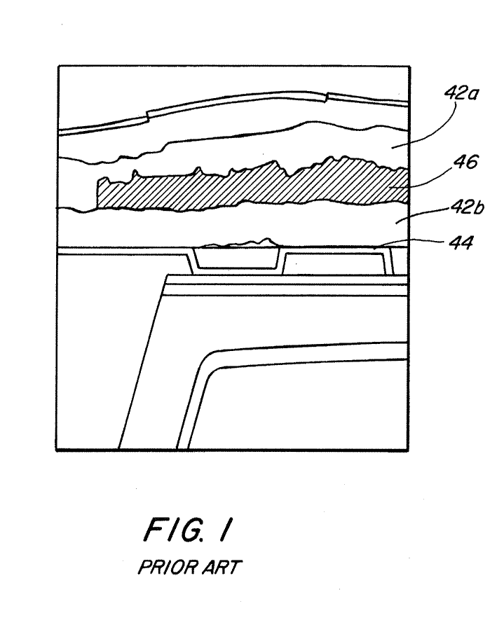

FIG. 1 depicts failure of a gold interconnect in conventional practices. As shown in FIG. 1, a conventional practice is to use a gold interconnect 42a and 42b over a structure 44. After the gold interconnect 42 is powered up for a certain period of time, the thermal impact delaminates the gold interconnect 42a from 42b and the underlying structure forming gap 46.

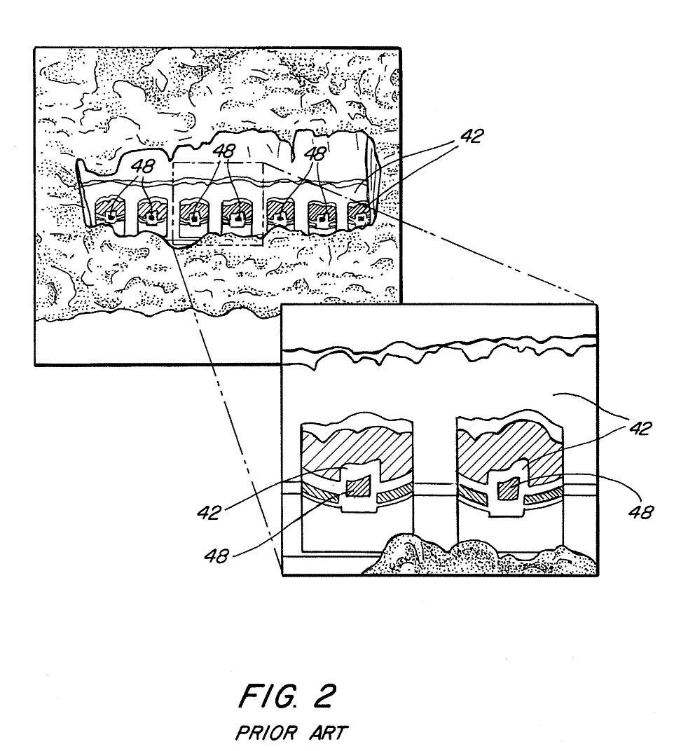

FIG. 2 depicts failure of a lower powered gold interconnect in conventional practices. As shown in FIG. 2, the gold interconnect 42 can fail even at a lower powered underlying gate area. The thermal impact created gaps 48 within the gold interconnect 42.

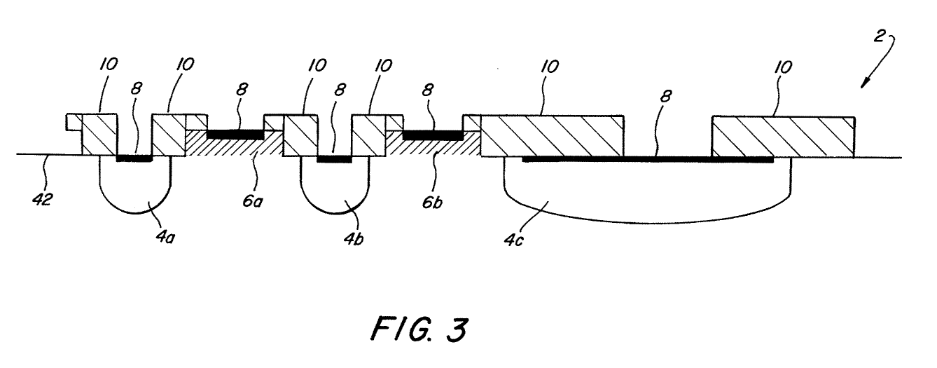

FIG. 3 depicts a side view of an ion implanted static induction transistor (I2SIT) 2 prior to the formation of a lower metal interconnect layer. As shown in FIG. 3, gate regions 4a, 4b and 4c and two source regions 6a and 6b are formed below the wafer surface 42. Gate region 4c can be a gate bus. Furthermore, the gate bus 4c can be a P-type implanted gate. I2SIT 2 also has Borophosphosilicate (BPSG) glass 10 as an insulating layer. Furthermore, Ni-silicide 8 can be formed on top of gate regions 4a and 4b, source regions 6a and 6b and gate bus 4c. Ni-silicide 8 may comprise Ni metal or any other Ni compound. It should be noted that surface 42 in FIG. 3 is not a straight line but follows the step up of source region 6a, across the top of 6a and 8 down the right side of 6a and back to 42. The same applies to source region 6b. In one embodiment, the source region is actually a mesa etched into an epi-layer of N+SiC.

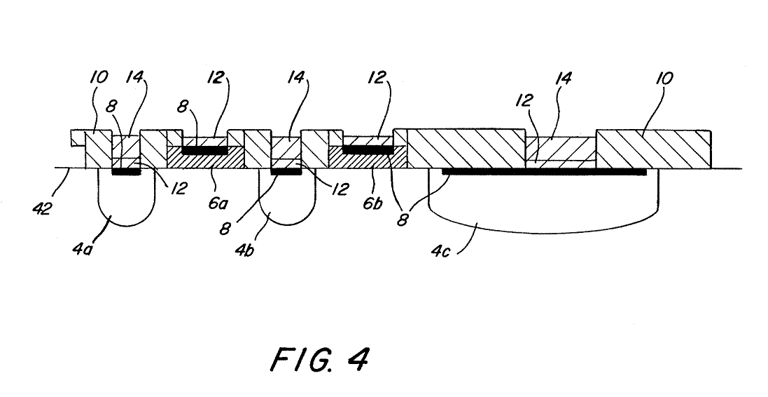

FIG. 4 depicts a side view of I2SIT 2 after formation of the lower metal interconnect layer. The lower metal interconnect layer may be formed in two separate steps. First, a layer of the combination of titanium and tungsten (TiW) is deposited on gate regions 4a, 4b and 4c as well as source regions 6a and 6b by sputtering through a resist mask. The sputtering can be done at about 1 kÅ to 3 kÅ to form first layer of TiW 12. A lift-off procedure is then used to delineate the respective regions.

Second, additional TiW is deposited on the gate regions 4a, 4b and gate bus 4c, by sputtering at approximately 2 kÅ to 4 kÅ followed by another lift-off procedure. This forms second layer of TiW 14. Alternatively molybdenum (Mo) may be sputtered in place of additional TiW. The second step advantageously enhances gate conductance and raises the height of the gate regions 4a, 4b and 4c, above the wafer surface 42 to approximately the height of the source regions 6a and 6b. Thus, second layer of TiW 14 can be at the same height at the gate regions 4a, 4b and 4c as first layer of TiW 12 at the source regions 6a and 6b.

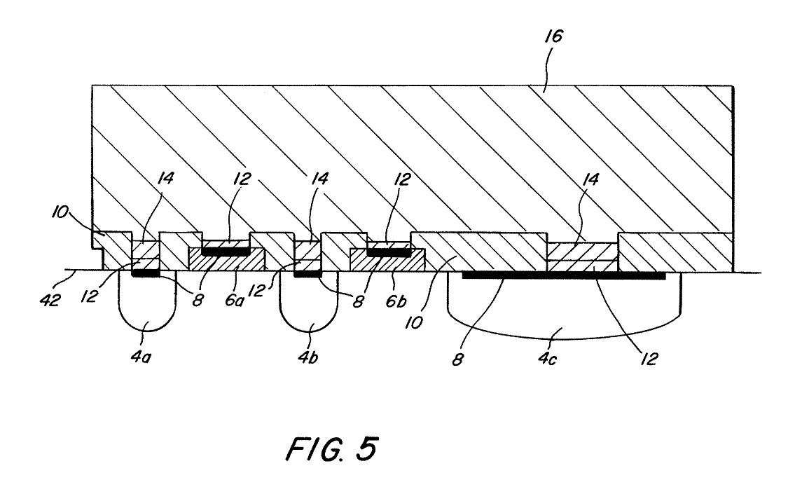

FIG. 5 depicts a side view of the I2SIT 2 after deposition of dielectric stack 16. Dielectric material such as tetra-ethyloxysilane (TEOS), silicon dioxide (SO2), silicon nitride (Si3N4), phosphorous doped silicon oxide glass, etc., is deposited as dielectric stack 16. A combination of dielectric materials may also be used.

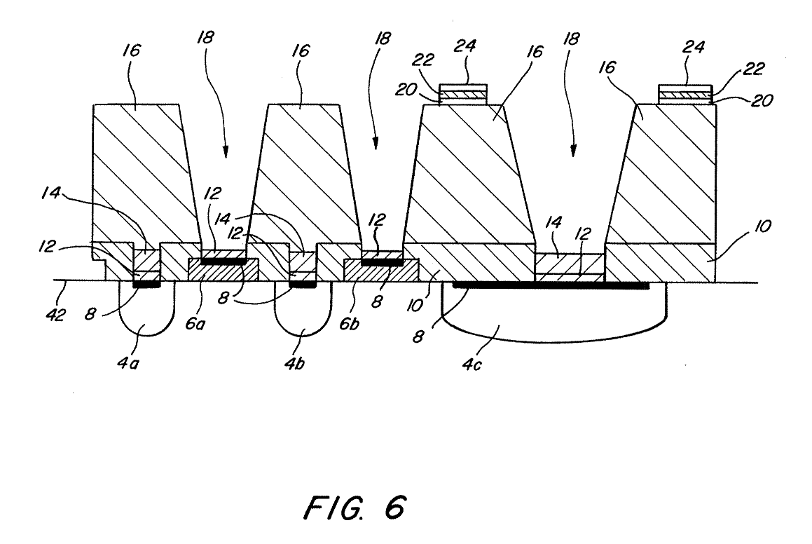

FIG. 6 depicts a side view of the I2SIT 2 after dielectric delineation and etch stop formation. Windows 18 to the lower metal interconnect layer such as second layer of TiW 14 and first layer of TiW 12 are then opened through dielectric stack 16. Next, etch stop regions for an upper metal interconnect layer are formed, for example, in the field area and between the gate and the adjacent source regions.

As can be seen in FIG. 6, the etch stop region is formed from a stack of thin metals and comprises a layer of Ti 20, followed by a layer of Au 22 and finally a layer of Ti 24. In one embodiment, layer of Ti 20, layer of Au 22 and layer of Ti 24 are sputtered at approximately 200 Å, 300 Å and 200 Å, respectively and then patterned through a photo-resist lift-off. However, the etch stop region may also comprise other metals such as a layer of Ti, a layer of Cr and a layer of Ti.

The etch stop region for the upper metal interconnect layer compensate for the non-uniformity of the upper metal interconnect layer etching process due to the thickness of that layer, which can cause metal lifting if not executed property. The interconnect layer can have a thickness in the order of micrometers. Formation of these etch stop regions advantageously overcomes this difficulty.

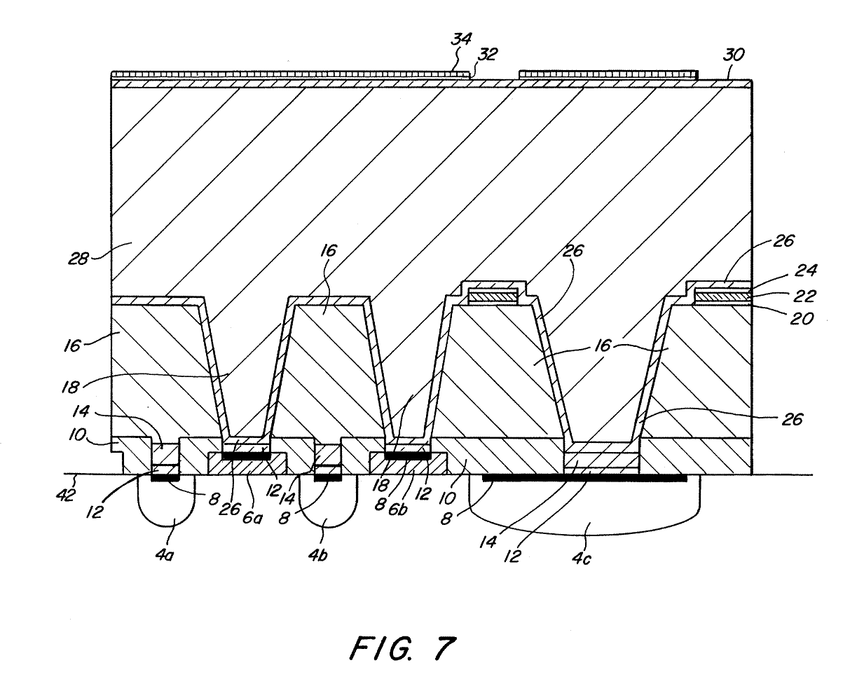

FIG. 7 depicts a side view of the I2SIT 2 after the upper metal interconnect layer is formed by globally sputtering a stack of metals in combination with a chemical vapor deposition of W. The metal stack includes for example, a layer of TiW 24, a layer of W 26 and a layer of TiW 30. In an exemplary embodiment, the layer of TiW 24 can have a thickness of approximately 1 to 2 kÅ, the layer of W 26 can have a thickness of approximately 5 to 50 kÅ and the layer of TiW 30 can have a thickness of approximately 1 to 2 kÅ.

A metal layer comprising a layer of Pt 34 on top of a layer of Ti 32 is then sputtered through a patterned resist and lift-off process. The layer of Ti 32 can be approximately 200 to 500 Å, while layer of Pt 34 can be approximately 200 to 2000 Å. In one embodiment, layer of Ti 32 and layer of Pt 34 may be used for a direct Pt or Au wire bond when layer of Ti 32 and layer of Pt 34 is sputtered with a thickness of over 1 kÅ. In another embodiment, when only an etch mask is desired, a thinner layer of Pt 34 may be used. The thinner layer of Pt 34 can be 200 to 800 Å. The thinner layer of Pt 34 can reduce thermal stress due to its similarity in thermal expansion coefficients of the layer of Ti 32 combined with the layer of Pt 34 and that of the underlying upper metal interconnect layer.

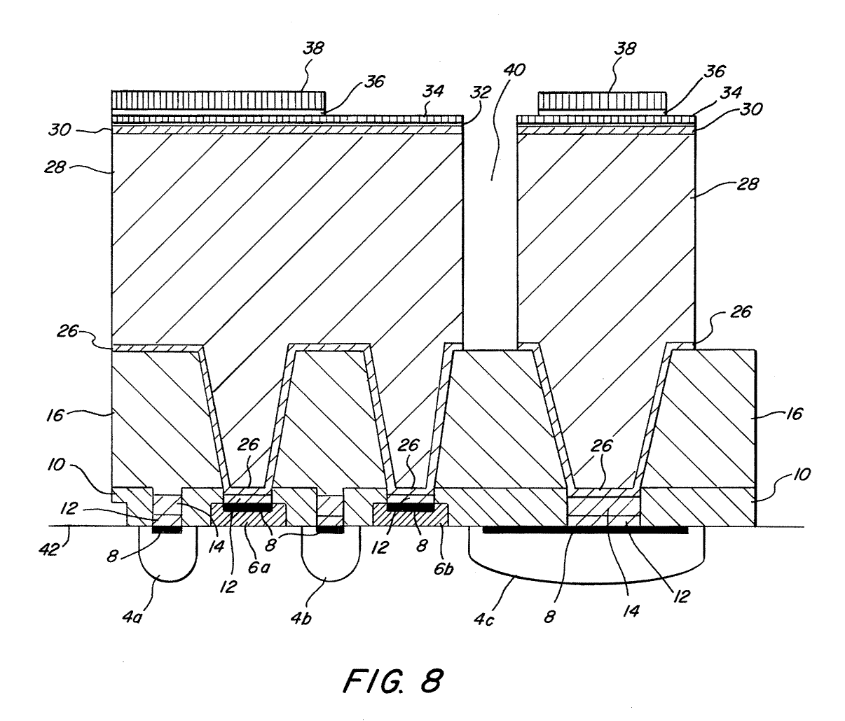

As shown in FIG. 8, reactive ion etching (RIE) may be used to open windows 40 through the upper metal interconnect layer to the etch stop regions. The RIE may be stopped, for example, at the upper layer of each etch stop region such as layer of Ti 24. A wet etch may then be used to etch off the thin, intermediate layer of each etch stop region such as layer of Au 22. Furthermore, the RIE may penetrate the final layer of each etch stop region such as layer of Ti 20 to reach the underlying dielectric material 16. Layers 36 and 38 can be Ti and Gold layers to stop oxidation of W and TiW and make wire-bonding easier. In this embodiment, the metal between the gate bus 4c and the adjacent source 4b, as well as the metal between the gate bus 4c and the field area, are separated.

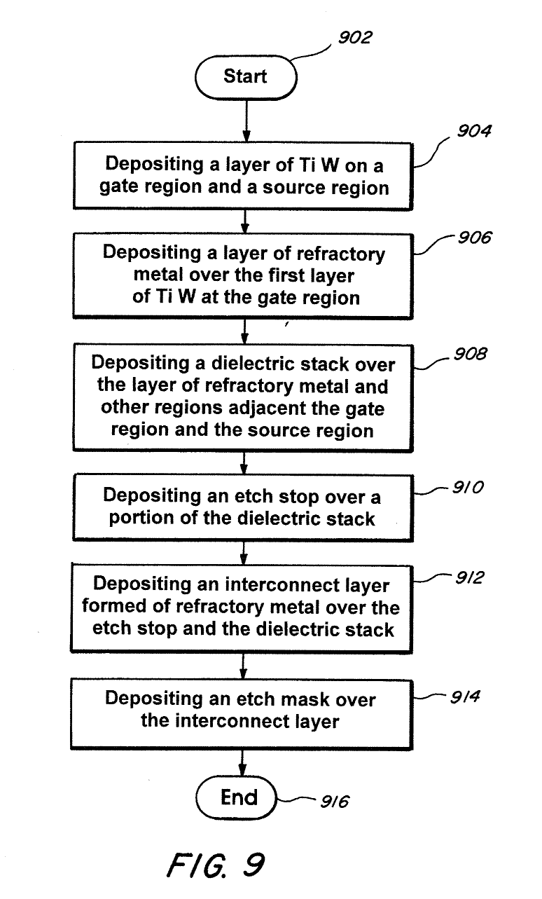

FIG. 9 is a flowchart of an exemplary method for forming a semiconductor power device according to an embodiment of the disclosure. Although the steps are shown in a particular order, it is understood that the steps can be performed in various orders. The method for forming a semiconductor power devices begins in step 902. In step 904, first layer of TiW 12 is deposited on gate regions 4a, 4b and 4c and source regions 6a and 6b. In step 906, a layer of refractory metal is deposited over first layer of TiW 12 over the gate regions such that the layer of refractory metal at the gate regions 4a, 4b and 4c is the same height as the first layer of TiW 12 over the source regions 6a and 6b. The layer of refractory metal can be second layer of TiW 14. The layer of refractory metal can also be a layer of Mo.

In step 908, dielectric stack 16 is deposited over the layer of refractory metal and other regions adjacent gate regions 4a, 4b and 4c and source regions 6a and 6b. Dielectric stack 16 can be formed from dielectric material such as tetra-ethyloxysilane (TEOS), silicon dioxide (SO2), silicon nitride (Si3N4), phosphorous doped silicon oxide glass, etc. A combination of dielectric materials may also be used to form dielectric stack 16.

In step 910, an etch stop is deposited over dielectric stack 16. The etch stop can be formed, for example, in the field area and between the gate and the adjacent source regions. The etch stop region are formed from a stack of thin metals and comprises layer of Ti 20, followed by layer of Au 22 and finally layer of Ti 24. Layer of Ti 20, layer of Au 22 and layer of Ti 24 are sputtered at approximately 200 Å, 300 Å and 200 Å respectively and then patterned through a photo-resist lift-off. However, the etch stop regions can also be other metals such as a layer of Ti, a layer of Cr and a layer of Ti, etc.

In step 912, an interconnect layer formed of refractory metal is deposited over the etch stop and the dielectric stack 16. This interconnect layer is the upper metal interconnect layer. The upper metal interconnect layer is formed by globally sputtering a stack of metals in combination with a chemical vapor deposition of W. The metal stack includes for example, a layer of TiW 24, a layer of W 26 and a layer of TiW 30. The layer of TiW 24 can have a thickness of approximately 1 to 2 kÅ, the layer of W 26 can have a thickness of approximately 5 to 50 kÅ and the layer of TiW 30 can have a thickness of approximately 1 to 2 kÅ.

In step 914, an etch mask is deposited over the interconnect layer. The etch mask can be a metal layer, such as for example, a layer of Pt 34 on top of a layer of Ti 32 which are then sputtered through a patterned resist and lift-off process. The layer of Ti 32 can be approximately 200 to 500 Å, while layer of Pt 34 can be approximately 200 to 2000 Å.

In one embodiment, layer of Ti 32 and layer of Pt 34 may be used for a direct Pt or Au wire bond when layer of Ti 32 and layer of Pt 34 is sputtered with a thickness of over 1 kÅ. In another embodiment, when only an etch mask is desired, a thinner layer of Pt 34 may be used. The thinner layer of Pt 34 can be 200 to 800 Å. The thinner layer of Pt 34 can reduce thermal stress due to its similarity in thermal expansion coefficients of the layer of Ti 32 combined with the layer of Pt 34 and that of the underlying upper metal interconnect layer.

In step 916, RIE is used to open windows 40 through the upper metal interconnect layer to the etch stop regions. The RIE may be stopped, for example, at the upper layer of each etch stop region such as layer of Ti 24. A wet etch may then be used to etch off the thin, intermediate layer of each etch stop region such as layer of Au 22. Furthermore, the RIE may penetrate the final layer of each etch stop region such as layer of Ti 20 to reach the underlying dielectric material 16. In this embodiment, the metal between the gate bus 4c and the adjacent source 4b, as well as the metal between the gate bus 4c and the field area, are separated.

The method for completing a semiconductor power device ends at step 916.

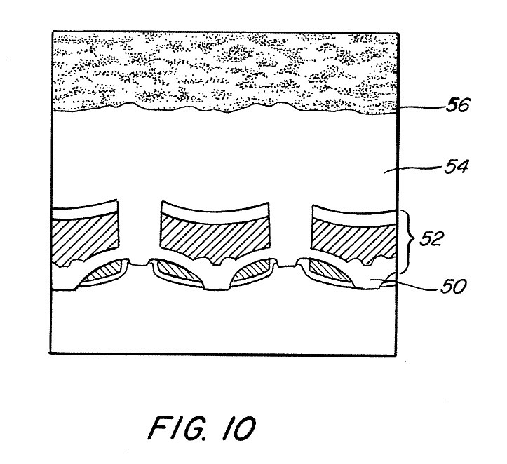

FIG. 10 depicts an embodiment of the disclosure. The embodiment comprises a layer of refractive metal 50, a dielectric stack 52, an interconnect 54 and an etch mask 56. The refractive metal can be a layer of TiW, Mo, or a combination thereof. Dielectric material such as tetra-ethyloxysilane (TEOS), silicon dioxide (SO2), silicon nitride (Si3N4), phosphorous doped silicon oxide glass, etc., is deposited as dielectric stack 52. A combination of dielectric materials may also be used. Interconnect 54 is a layer of TiW, a layer of W and a layer of TiW. Etch mask 54 is a layer of Ti, Pt, or a combination of Ti and Pt.

As can be seen in FIG. 10, there is no delamination of interconnect 54. Furthermore, layer of refractive metal 50 also does not exhibit any failures as gap 48 of FIG. 2 is absent.

The embodiments described herein are exemplary and non-limiting. The scope of the disclosure is defined solely by the appended claims when accorded a full range of equivalence with many variations and modifications naturally occurring to one of ordinary skill in the art without departing from the scope of the claims.

What is claimed is:

1. A method for forming a semiconductor power device comprising:
depositing a first layer of TiW (12) on a gate region (4a, 4b, 4c) and a source region (6a, 6b);
depositing a second layer of refractory metal (14) over the first layer of TiW (12) at the gate region (4a, 4b, 4c);
depositing a dielectric stack (16) over the second layer of refractory metal (14) and a portion of the first layer of TiW (12);
depositing an etch stop layer (20, 22, 24) over a portion of the dielectric stack (16);
depositing an interconnect layer (26, 28, 30) over the etch stop layer (20, 22, 24) and the dielectric stack (16); and
depositing an etch mask (32, 34) over the interconnect layer (26, 28, 30).

2. The method of claim 1 wherein after the second layer of refractory metal is deposited, the second layer of refractory metal is at substantially a same height at the gate region as the first layer of TiW at the source region.

3. The method of claim 1 wherein the step of depositing the layer of refractory metal over the first layer of TiW at the gate region further comprises depositing a second layer of TiW over the first layer of TiW.

4. The method of claim 1 wherein the step of depositing the layer of refractory metal over the first layer of TiW at the gate region further comprises depositing a Mo layer over the first layer of TiW.

5. The method of claim 1 wherein the step of depositing the interconnect layer over the dielectric stack further comprises depositing TiW and W.

6. The method of claim 5 wherein the step of depositing the interconnect layer over the dielectric stack further comprises depositing a third layer of TiW, depositing a layer of W over the third layer of TiW and depositing a fourth layer of TiW over the layer of W.

7. The method of claim 1 wherein the step of depositing the etch stop layer over the dielectric stack further comprises depositing a first layer of Ti, depositing a layer of Au over the first layer of Ti and depositing a second layer of Ti over the layer of Au.

8. The method of claim 1 wherein the step of depositing the etch stop layer over the dielectric stack further comprises depositing a first layer of Ti, depositing a layer of NiCr over the first layer of Ti and depositing a second layer of Ti over the layer of NiCr.

9. The method of claim 1 wherein the step of depositing the etch stop layer over the dielectric stack further comprises depositing a first layer of Ti, depositing a layer of Cr over the first layer of Ti and depositing a second layer of Ti over the layer of Cr.

10. The method of claim 1 wherein the etch mask further comprises a layer of Ti, Pt, or a combination of Ti and Pt.

11. The method of claim 1 wherein the etch mask further comprises a patterned etch mask.

12. The method of claim 1 wherein the step of depositing the dielectric stack further comprises depositing at least one of Si₃N₄ and SiO₂.

13. A method for forming a semiconductor power device comprising:
depositing a first layer of TiW (12) on a gate region (4a, 4b, 4c) and a source region (6a, 6b);
depositing a second layer of refractory metal (14) over the first layer of TiW at the gate region (4a, 4b, 4c);
depositing a dielectric stack (16) over the second layer of refractory metal (14) and a portion of the first layer of TiW (12);
depositing an etch stop layer (20, 22, 24) over a portion of the dielectric stack (16);
depositing an interconnect layer (26, 28, 30) formed of TiW and W over the etch stop layer (20, 22, 24) and the dielectric stack (16); and
depositing an etch mask (32, 34) formed of a layer of Ti, Pt, or a combination of Ti and Pt over the interconnect layer (26, 28, 30).

14. The method of claim 13 wherein after the second layer of refractory metal is deposited, the second layer of refractory metal is at substantially a same height at the gate region as the first layer of TiW at the source region.

15. The method of claim 13 wherein the step of depositing the layer of refractory metal over the first layer of TiW at the gate region further comprises depositing a second layer of TiW over the first layer of TiW.

16. The method of claim 13 wherein the step of depositing the layer of refractory metal over the first layer of TiW at the gate region further comprises depositing a Mo layer over the first layer of TiW.

17. The method of claim 13 wherein the step of depositing an interconnect layer over the dielectric stack further comprises depositing a second layer of TiW, depositing a layer of W over the second layer of TiW and depositing a third layer of TiW over the layer of W.

18. The method of claim 13 wherein the step of depositing an etch stop layer over the dielectric stack further comprises depositing a first layer of Ti, depositing a layer of Au over the first layer of Ti and depositing a second layer of Ti over the layer of Au.

19. The method of claim 13 wherein the step of depositing an etch stop layer over the dielectric stack further comprises depositing a first layer of Ti, depositing a layer of NiCr over the first layer of Ti and depositing a second layer of Ti over the layer of NiCr.

20. The method of claim 13 wherein the step of depositing an etch stop layer over the dielectric stack further comprises depositing a first layer of Ti, depositing a layer of Cr over the first layer of Ti and depositing a second layer of Ti over the layer of Cr.

21. The method of claim 13 wherein the etch mask further comprises a patterned etch mask.

22. The method of claim 13 wherein the step of depositing a dielectric stack over the layer of refractory metal and other regions adjacent the gate region and the source region further comprises depositing Si₃N₄ and SiO₂.

23. A semiconductor power device comprising:
a gate region (4a, 4b, 4c) with a first layer of TiW (12) over the gate region;
a source region (6a, 6b) with a first layer of TiW (12) over the source region;
a second layer of refractory metal (14) over the first layer of TiW (12) at the gate region (4a, 4b, 4c);
a dielectric stack (16) over the second layer of refractory metal (14) and a portion of the first layer of TiW (12);
an etch stop layer (20, 22, 24) over a portion of the dielectric stack (16);
an interconnect layer (26, 28, 30) formed of refractory metal over the etch stop layer (20, 22, 24) and the dielectric stack (16); and
an etch mask (32, 34) over the interconnect layer (26, 28, 30).

24. The semiconductor power device of claim 23 wherein the layer of refractory metal is at relatively the same height at the gate region as the first layer of TiW at the source region.

25. The semiconductor power device of claim 23 wherein the gate region is formed of TiW.

26. The semiconductor power device of claim 23 wherein the gate region is formed of Mo.

27. The semiconductor power device of claim 23 wherein the source region is formed of TiW.

28. The semiconductor power device of claim 23 wherein the source region is formed of Mo.

29. The semiconductor power device of claim 23 wherein the layer of refractory metal is a second layer of TiW over the first layer of TiW at the gate region.

30. The semiconductor power device of claim 23 wherein the refractory metal is a layer of Mo over the first layer of TiW at the gate region.

31. The semiconductor power device of claim 23 wherein the interconnect layer has TiW and W.

32. The semiconductor power device of claim 31 wherein the interconnect layer is a third layer of TiW, a layer of W over the third layer of TiW and a fourth layer of TiW over the layer of W.

33. The semiconductor power device of claim 23 wherein the etch stop layer is a first layer of Ti, a layer of Au over the first layer of Ti and a second layer of Ti over the layer of Au.

34. The semiconductor power device of claim 23 wherein the etch stop layer is a first layer of Ti, a layer of NiCr over the first layer of Ti and a second layer of Ti over the layer of NiCr.

35. The semiconductor power device of claim 23 wherein the etch stop layer is a first layer of Ti, a layer of Cr over the first layer of Ti and a second layer of Ti over the layer of Cr.

36. The semiconductor power device of claim 23 wherein the etch mask further comprises a layer of Ti, Pt, or a combination of Ti and Pt.

37. The semiconductor power device of claim 23 wherein the etch mask further comprises a patterned etch mask.

38. The semiconductor power device of claim 36 wherein the dielectric stack over the layer of refractory metal and other regions adjacent the gate region and the source region has Si₃N₄ and SiO₂.
